(19) United States
(12) Patent Application Publication
(10) Pub. No.: US 2023/0223904 A1
(43) Pub. Date: Jul. 13, 2023

(54) LOW NOISE AMPLIFIER AND OPERATING METHOD THEREOF

(71) Applicant: SAMSUNG ELECTRO-MECHANICS CO., LTD., Suwon-si (KR)

(72) Inventor: Mooyoung RYU, Suwon-si (KR)

(73) Assignee: SAMSUNG ELECTRO-MECHANICS CO., LTD., Suwon-si (KR)

(21) Appl. No.: 17/864,994

(22) Filed: Jul. 14, 2022

(30) Foreign Application Priority Data
Jan. 10, 2022 (KR) 10-2022-0003435

(51) Int. Cl. H03F 3/193

(52) U.S. Cl. CPC H03F 3/193; H03F 2200/294; H03F 2200/451

(57) ABSTRACT

A low noise amplifier is provided. The low noise amplifier includes a first transistor that receives a radio frequency (RF) signal through a control terminal, a second transistor that forms a cascode structure together with the first transistor, and receives an output signal of the first transistor through a first terminal, and a third transistor that forms a cascode structure together with the second transistor, and receives an output signal of the second transistor through the first terminal. The first to third transistors perform an amplification operation in response to application of a first power source voltage, and the first and second transistors or the first and third transistors perform an amplification operation in response to application of a second power source voltage.

### CROSS-REFERENCE TO RELATED APPLICATIONS

This application claims the benefit under 35 USC § 119(a) of Korean Patent Application No. 10-2022-0003435 filed on Jan. 10, 2022, in the Korean Intellectual Property Office, the entire disclosure of which is incorporated herein by reference for all purposes.

### BACKGROUND

### 1. Field

This disclosure relates to a low noise amplifier and an operation method thereof.

### 2. Description of the Background

A low noise amplifier (LNA) may be included in a receiving end of a mobile device and may amplify a weak signal received through an antenna into a signal that is strong against noise. This low noise amplifier is a circuit that determines noise performance of the receiver.

The low noise amplifier operates by a power source voltage supplied from the outside, and an internal circuit structure can be designed to correspond to one power source voltage. That is, the internal circuit structure of the low noise amplifier may be designed to suit the magnitude of one predetermined power source voltage in advance. However, a low noise amplifier designed to suit the magnitude of one power source voltage may not have a desired gain when the magnitude of the power source voltage is changed.

The above information is presented as background information only to assist with an understanding of the present disclosure. No determination has been made, and no assertion is made, as to whether any of the above might be applicable as prior art with regard to the disclosure.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a low noise amplifier includes a first transistor that receives a radio frequency (RF) signal through a control terminal, a second transistor that forms a cascode structure together with the first transistor, and receives an output signal of the first transistor through a first terminal of the second transistor, and a third transistor that forms a cascode structure together with the second transistor, and receives an output signal of the second transistor through a first terminal of the third transistor. The first to third transistors perform an amplification operation in response to application of a first power source voltage, and the first and second transistors or the first and third transistors perform an amplification operation in response to application of a second power source voltage.

The first power source voltage may be higher than the second power source voltage.

The low noise amplifier may further include a switch that is connected between the first terminal and a second terminal of the third transistor. The switch may perform a switching operation corresponding to the first and second power source voltages.

The switch may turn off in response to application of the first power source voltage. The switch may also be turn on in response to application of the second power source voltage.

The low noise amplifier may further include a switch that is connected between the first terminal and a second terminal of the second transistor. The switch may perform a switching operation corresponding to the first and second power source voltages.

The switch may turn off in response to application of the first power source voltage, and turn on in response to application of the second power source voltage.

The first terminal of the second transistor may be connected to a first terminal of the first transistor, the first terminal of the third transistor may be connected to a second terminal of the second transistor, and the first power source voltage or the second power source voltage may be applied to a second terminal of the third transistor.

The low noise amplifier may further include a first inductor that is connected between a second terminal of the first transistor and a ground, and a second inductor that is connected between a terminal to which the first power source voltage or the second power source voltage is input and the second terminal of the third transistor.

The control terminal of the first transistor, a control terminal of the second transistor, and a control terminal of the third transistor may be respectively applied with a bias voltage.

In another general aspect, a method includes amplifying a received Radio Frequency (RF) signal by operating N transistors (here, N is a natural number of 3 or more) that are connected in a cascode structure with each other when a power source voltage is a first power source voltage, and amplifying the RF signal by operating M transistors among the N transistors when the power source voltage is a second power source voltage. M is a natural number of less than the N.

The first power source voltage may be higher than the second power source voltage.

The amplifying of the RF signal by operating the less than the M transistors includes providing a bypassing path at opposite ends of at least one transistor among the less than the at least three transistors.

The providing of the bypassing path may include providing the bypassing path through a switch that is connected to the opposite ends of the at least one transistor.

When the first power source voltage is applied, the switch may be turned off, and when the second power source voltage is applied, the switch may be turned on.

The N transistors may include a first transistor that receives the RF signal, a second transistor connected with the first transistor with a cascode structure, and a third transistor connected with the second transistor with a cascode structure. The M transistors may include the first and second transistors or the first and third transistors.

In another general aspect, a low noise amplifier includes a first transistor that receives a radio frequency (RF) signal through a control terminal, a second transistor that receives an output signal of the first transistor through a first terminal of the second transistor, and a third transistor that receives an output signal of the second transistor through a first terminal of the third transistor. The first to third transistors perform an amplification operation in response to application of a first power source voltage. The first and second transistors or the first and third transistors perform an amplification operation in response to application of a second power source voltage.

The second transistor may form a cascode structure with the first transistor.

The second transistor may form a cascode structure with the third transistor.

Other features and aspects will be apparent from the following detailed description, the drawings, and the claims.

### BRIEF DESCRIPTION OF THE DRAWINGS

FIG. 1 illustrates a schematic view of a low noise amplifier, in accordance with one or more embodiments.

FIG. 2 illustrates an internal circuit structure of the low noise amplifier, in accordance with one or more embodiments.

FIG. 3 illustrates a circuit diagram of the low noise amplifier, in accordance with one or more embodiments.

FIG. 4A illustrates an operation state of the lower noise amplifier of FIG. 3 when the first power source voltage is applied.

FIG. 4B illustrates an operation state of the low noise amplifier in a case that the second power source voltage is applied.

FIG. 5 illustrates a circuit diagram of a low noise amplifier, in accordance with one or more embodiments.

FIG. 6 illustrates a graph illustrating a simulation result of the low noise amplifier, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION OF THE EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known after an understanding of this disclosure may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of this disclosure. Terms, such as those defined in commonly used dictionaries, are to be interpreted as having a meaning that is consistent with their meaning in the context of the relevant art and of this disclosure, and are not to be interpreted in an idealized or overly formal sense unless expressly so defined herein.

Also, in the description of example embodiments, detailed description of structures or functions that are thereby known after an understanding of this disclosure will be omitted when it is deemed that such description will cause ambiguous interpretation of the example embodiments.

Throughout this specification, the RF signal may have a format of, but not limited to, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access (HSPA), high-speed downlink packet access (HSDPA), high-speed uplink packet access (HSUPA), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other arbitrary wireless and wired protocols designated later, but is not limited thereto.

Additionally, unless explicitly described to the contrary, the word “comprise”, and variations such as “comprises” or “comprising”, will be understood to imply the inclusion of stated elements but not the exclusion of any other elements.

Herein, it is noted that use of the term “may” with respect to an example, for example, as to what an example may include or implement, means that at least one example exists in which such a feature is included or implemented while all examples are not limited thereto.

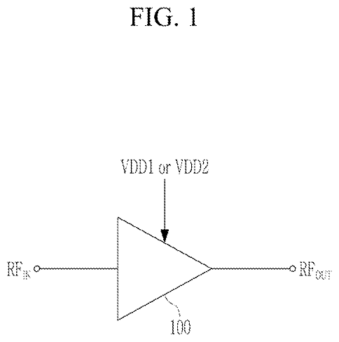

FIG. 1 illustrates a schematic view of a low noise amplifier, in accordance with one or more embodiments.

As shown in FIG. 1, a low noise amplifier 100 may include an RF input terminal RF_{IN} and an RF output terminal RF_{OUT}, and may amplify an RF signal input to the RF input terminal RF_{IN} and output the amplified RF signal to the RF output terminal RF_{OUT}. Additionally, the low noise amplifier 100 may operate by externally receiving a first power source voltage VDD1 or a second power source voltage VDD2.

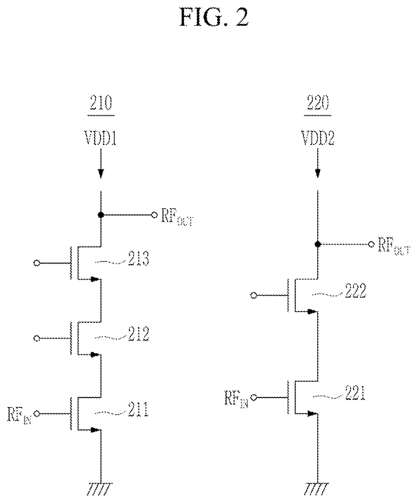

In an example, the first power source voltage VDD1 may be higher than the second power source voltage VDD2. For example, the first power source voltage VDD1 may be 1.8 V, and the second power source voltage VDD2 may be 1.2 V. An internal circuit structure of the low noise amplifier 100 may be changed according to the power source voltage (VDD1 or VDD2) supplied from the outside, and this will be described in more detail with reference to FIG. 2.

FIG. 2 illustrates an internal circuit structure of the low noise amplifier 100, in accordance with one or more embodiments.

In FIG. 2, the reference numeral 210 indicates an internal circuit structure in the case that the low noise amplifier 100 receives the first power source voltage VDD1. Referring to 210 of FIG. 2, when the first power source voltage VDD1 is applied, the low noise amplifier 100 may form a cascode structure in which at least three transistors are stacked. For an example, a (for example, first) transistor 211, a (for example, second) transistor 212, and a (for example, third) transistor 213 may be stacked to form a cascode structure with each other. An RF signal may be input to a control terminal of the first transistor 211, and a final amplified signal may be output from a drain of the third transistor 213.

Additionally, in FIG. 2, the reference numeral 220 indicates an internal circuit structure of a case that the low noise amplifier 100 is supplied with the second power source voltage VDD2. Referring to 220 of FIG. 2, when the second power source voltage VDD2 is applied, the low noise amplifier 100 may form a cascode structure in which at least two transistors are stacked. For an example, a (for example, first) transistor 221 and a (for example, second) transistor 222 may be stacked to form a cascode structure with each other. An RF signal may be input to a control terminal of the transistor 221, and a final amplified signal may be output to a drain of the transistor 222. In other words, when the second power source voltage VDD2 is applied, the number of stacked transistors may be smaller than when the first power source voltage VDD1 is applied. Hereinafter, for better understanding and ease of description, a case in which three transistors are stacked in a cascode structure at the first power source voltage VDD1 and two transistors are stacked in a cascode structure at the second power source voltage VDD2 will be described, but the number of stacked transistors can be changed and the embodiments are not limited thereto.

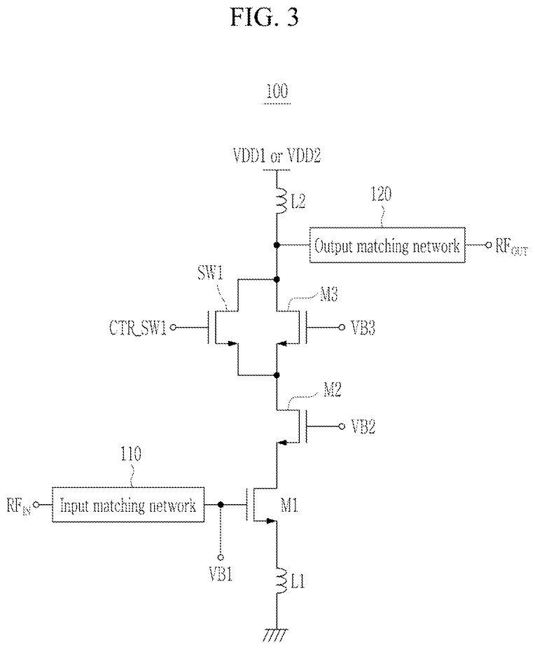

FIG. 3 is a circuit diagram of the low noise amplifier, in accordance with one or more embodiments.

As shown in FIG. 3, the low noise amplifier 100 may include an input matching network 110, a transistor M1, a transistor M2, a transistor M3, a switch SW1, and an output matching network 120. In addition, the low noise amplifier 100 may further include an inductor L1 and an inductor L2.

In FIG. 3, the transistors M1 to M3 and the switch SW1 may be implemented with various transistors such as an electric field effect transistor (FET) and a bipolar transistor. Additionally, in FIG. 3, the transistors M1 to M3 and the switch SW1 are illustrated as an N-type, but may be replaced with a P-type. Hereinafter, for better understanding and ease of description, it is assumed that the transistors M1 to M3 and the switch SW1 are FETs, but may be replaced with other transistors.

The input matching network 110 may be connected between an RF input terminal RF_{IN} and a control terminal (e.g., a gate) of the transistor M1, and may perform impedance matching between the input RF signal and the transistor M1. The input matching network 110 may be implemented with a combination of at least one of an inductor and a capacitor.

The transistor M1 is an amplifying transistor, and an RF signal to be amplified may be input to the gate of the transistor M1. A bias voltage VB1 may be applied to the gate of the transistor M1. The transistor M1 may perform an amplification operation by the bias voltage VB1. Then, the amplified signal may be output to a drain of the transistor M1.

The inductor L1 may be connected between a source of the transistor M1 and a ground. The inductor L1 is a degeneration circuit, which can improve the impedance matching of the input matching network 110. Accordingly, the inductor L1 may optimize a gain and a noise figure of the low noise amplifier 100. When the transistor M1 is implemented as a bipolar transistor, the inductor L1 may provide emitter degeneration. Additionally, when the transistor M1 is implemented as an electric field effect transistor (FET), the inductor L1 may provide source degeneration. The inductor L1 may be replaced with a resistor to serve as a degeneration circuit.

The transistor M2 may form a cascode structure together with the transistor M1, and may amplify an output signal of the transistor M1. A source of the transistor M2 is connected to the drain of the transistor M1, and an RF signal to be amplified may be input to the source of the transistor M2. That is, the source of the transistor M2 may receive and amplify the RF signal output from the drain of the transistor M1, and the drain of the transistor M2 may output the amplified signal. Additionally, a bias voltage VB2 may be applied to the gate of the transistor M2. The transistor M2 may perform an amplification operation by the bias voltage VB2.

The transistor M3 may form a cascode structure together with the transistor M2, and may amplify the output signal of the transistor M2. A source of the transistor M3 may be connected to the drain of the transistor M2, and an RF signal to be amplified may be input to a source of the transistor M3. That is, the source of the transistor M3 receives and amplifies the RF signal output from the drain of the transistor M2, and a drain of the transistor M3 may finally output the amplified signal. Additionally, a bias voltage VB3 may be applied to the gate of the transistor M3. The transistor M3 may perform an amplification operation by the bias voltage VB3.

The switch SW1 may be connected to opposite ends of the transistor M3, and may perform a switching operation by a switching control signal CTR_SW1. A first terminal (e.g., a source) of the switch SW1 may be connected to the source of the transistor M3, and a second terminal (e.g., a drain) of the switch SW1 may be connected to the drain of the transistor M3. Additionally, the switching control signal CTR_SW1 may be input to a control terminal (e.g., a gate) of the switch SW1. In an example, the switching control signal CTR_SW1 may include a switch-on signal CTR_SW1_ON and a switch-off signal CTR_SW1_OFF.

When the first power source voltage VDD1 is applied to the low noise amplifier 100, the switching control signal CTR_SW1 becomes a switch-off signal CTR_SW1_OFF. When the switch SW1 is turned off, the transistor M3 may perform a normal amplification operation. Accordingly, the low noise amplifier 100 may perform an amplification operation through the three transistors M1, M2, and M3 stacked with each other and forming a cascode structure.

Additionally, when the second power source voltage VDD2 is applied to the low noise amplifier 100, the switching control signal CTR_SW1 becomes the switch-on signal CTR_SW1_ON. When the switch SW1 is turned on, a bypassing path is created between the drain and the source of transistor M3. Thus, the transistor M3 cannot perform a normal amplification operation. Accordingly, the low noise amplifier 100 may perform an amplification operation through the two transistors M1 and M2 stacked with each other and forming a cascode structure.

The inductor L2 may be connected between a terminal to which a power source voltage VDD1 or VDD2 is applied and the drain of the transistor M3. The transistor M3, the transistor M2, and the transistor M1 may receive a power source voltage VDD1 or VDD2 through the inductor L2. In an example, the inductor L2 may perform an RF choke function or an output impedance matching function, but is not limited thereto.

The output matching network 120 may be connected between the drain of the transistor M3 and an RF output terminal RF_{OUT}, and may perform output impedance matching. The output matching network 120 may be implemented with a combination of at least one of an inductor and a capacitor. As a non-limiting example, the inductor L2 may be included in the output matching network 120.

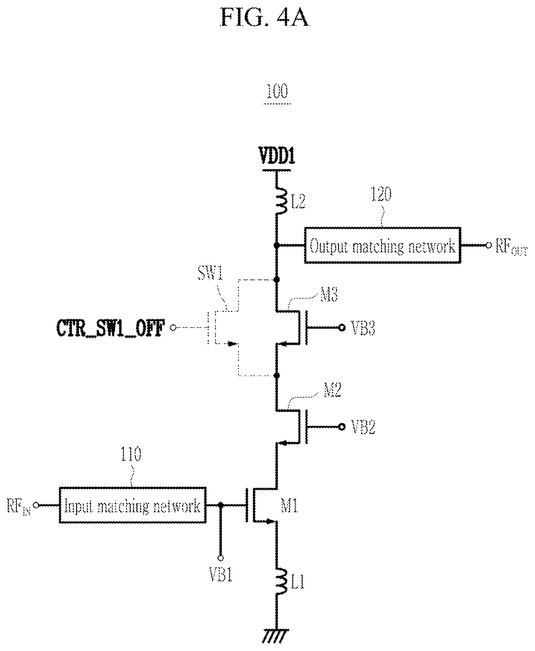

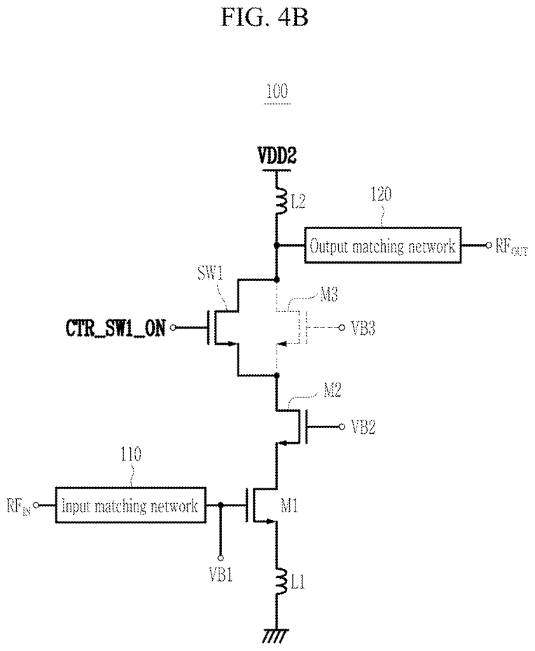

As described above, in the low noise amplifier 100 according to the embodiment, the number of transistors performing the amplification operation is changed according to the externally supplied power source voltage VDD1 or VDD2, and this will be described in detail with reference to FIG. 4A and FIG. 4B. FIG. 4A shows an operation state of the lower noise amplifier 100 of FIG. 3 when the first power source voltage VDD1 is applied.

In instances in which the first power source voltage VDD1 is applied, the switching control signal CTR_SW1 may become a switch-off signal CTR_SW1_OFF. Since the switch SW1 is turned off, the transistor M3 can perform the normal amplification operation. Accordingly, the transistors M1, M2, and M3 may be stacked while forming a cascode structure with each other. The RF signal input to the RF input terminal RF_{IN} is amplified by the transistor M1, the transistor M2, and the transistor M3. The final amplified signal is output to the RF output terminal RF_{OUT} through the drain terminal of the transistor M3.

The following Equation 1 indicates final output resistance rₒᵤₜ₃ in a case that the three transistors M1, M2, and M3 are stacked in a cascode structure.

rₒᵤₜ₃=rₒ₁+r₀₂+r₀₃+gₘ₂rₒ₁rₒ₂+gₘ₃rₒ₁rₒ₃+gₘ₃rₒ₂rₒ₃+gₘ₂gₘ₃rₒ₁rₒ₂rₒ₃ Equation 1

In Equation 1, rₒ₁ denotes output resistance of the transistor M1, rₒ₂ denotes output resistance of the transistor M2, and rₒ₃ denotes output resistance of the transistor M3. In addition, gₘ₂ denotes transconductance of the transistor M2, and gₘ₃ denotes transconductance of the transistor M3.

FIG. 4B shows an operation state of the low noise amplifier 100 in a case that the second power source voltage VDD2 is applied.

In instances in which the second power source voltage VDD2 is applied, the switching control signal CTR_SW1 may become a switch-on signal CTR_SW1_ON. Since the switch SW1 is turned on, the transistor M3 cannot perform a normal amplification operation. Accordingly, only the transistors M1 and M2 are stacked while forming a cascode structure with each other. An RF signal input to the RF input terminal RF_{IN} is amplified by the transistor M1 and the transistor M2. The finally amplified signal is output to the RF output terminal RF_{OUT} through the drain terminal of the transistor M2 and the switch SW1.

The following Equation 2 indicates final output resistance rₒᵤₜ₂ in a case that two transistors M1 and M2 are stacked in a cascode structure.

rₒᵤₜ₂=rₒ₁+rₒ₂+gₘ₂rₒ₁rₒ₂ Equation 2

In Equation 2, rₒ₁ denotes output resistance of the transistor M1, and rₒ₂ denotes output resistance of the transistor M2. In addition, gₘ₂ denotes transconductance of the transistor M2.

Referring to Equation 1 and Equation 2, when the first power source voltage VDD1 that is higher than the second power source voltage VDD2 is applied, the low noise amplifier 100 may have a higher gain. Under the condition that the same current is applied, the higher the output resistance, the higher the gain. Accordingly, the low noise amplifier 100 may have a higher gain at the first power source voltage VDD1.

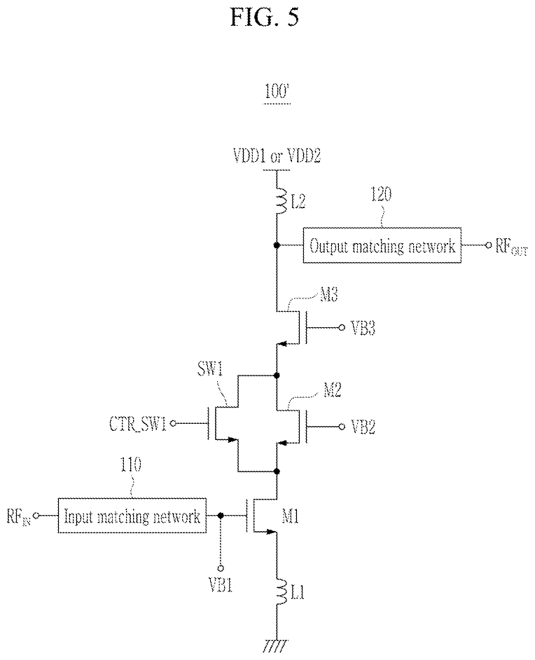

FIG. 5 is a circuit diagram of a low noise amplifier 100′, in accordance with one or more embodiments.

As shown in FIG. 5, the low noise amplifier 100′ is similar to the low noise amplifier 100 of FIG. 3, except for a location of a switch SW1.

Referring to FIG. 5, the switch SW1 is connected to opposite ends of a transistor M2 and may perform a switching operation by a switching control signal CTR_SW1. A first terminal (e.g., a source) of the switch SW1 may be connected to a source of a transistor M2, and a second terminal (e.g., a drain) of the switch SW1 may be connected to a drain of a transistor M2. In addition, the switching control signal CTR_SW1 may be input to a control terminal of the switch SW1. In an example, the switching control signal CTR_SW1 may include a switch-on signal CTR_SW1_ON and a switch-off signal CTR_SW1_OFF.

When a first power source voltage VDD1 is applied to the low noise amplifier 100′, the switching control signal CTR_SW1 becomes the switch-off signal CTR_SW1_OFF. When the switch SW1 is turned off, the transistor M2 may perform a normal amplification operation. Accordingly, the low noise amplifier 100′ may perform an amplification operation through the three transistors M1, M2, and M3 that are stacked while forming a cascode structure. Additionally, when a second power source voltage VDD2 is applied to the low noise amplifier 100′, the switching control signal CTR_SW1 becomes the switch-on signal CTR_SW1_ON. When the switch SW1 is turned on, a bypassing path is created between the drain and the source of the transistor M2. Accordingly, the transistor M2 cannot perform a normal amplification operation. The low noise amplifier 100 may perform an amplification operation through the two transistors M1 and M3 stacked with each other while forming a cascode structure.

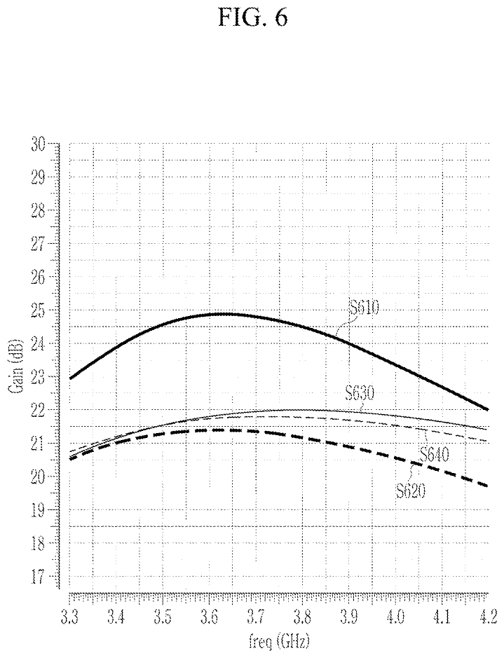

FIG. 6 is a graph illustrating a simulation result of the low noise amplifier, in accordance with one or more embodiments.

In FIG. 6, the first power source voltage VDD1 was assumed to be 1.8 V, and the second power source voltage VDD2 was assumed to be 1.2 V. The horizontal axis represents a frequency, and the vertical axis represents a gain. S610 shows a case in which the first power source voltage VDD1 (1.8 V) of FIG. 3 is applied in the low noise amplifier 100, and S620 shows a case where the second power source voltage (VDD2, 1.2 V) is applied to the low noise amplifier 100 of FIG. 3. S630 shows a case that a first power source voltage VDD1 (1.8 V) is applied in a conventional low noise amplifier structure, and S640 shows a case that a second power source voltage VDD2 (1.2 V) is applied to the conventional low noise amplifier. Here, the conventional low noise amplifier shows a case in which two fixed transistors are stacked in a cascode structure, not when the number of stacked transistors is changed according to a power source voltage.

Referring to S630 and S640, it can be observed that the conventional low noise amplifier has little difference in gain depending on the power source voltage. In an example, referring to S610 and S620, the low noise amplifier 100 according to the embodiment may have a gain that is higher at the first power source voltage VDD1 (1.8 V) than at the second power source voltage VDD2 (1.2 V) by more than 5 dB. That is, the low noise amplifier 100 according to the embodiment may provide a gain that is suitable for the power source voltage.

According to at least one embodiment of the embodiments, it is possible to provide a gain suitable for the power source voltage by changing the number of stacked transistors according to the power source voltage.

While this disclosure includes specific examples, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A low noise amplifier comprising:
a first transistor configured to receive a radio frequency (RF) signal through a control terminal;
a second transistor that forms a cascode structure together with the first transistor, and is configured to receive an output signal of the first transistor through a first terminal of the second transistor; and
a third transistor that forms a cascode structure together with the second transistor, and is configured to receive an output signal of the second transistor through a first terminal of the third transistor,
wherein the first to third transistors are configured to perform an amplification operation in response to application of a first power source voltage, and the first and second transistors or the first and third transistors are configured to perform an amplification operation in response to application of a second power source voltage.

2. The low noise amplifier of claim 1, wherein the first power source voltage is higher than the second power source voltage.

3. The low noise amplifier of claim 1, further comprising a switch that is connected between the first terminal and a second terminal of the third transistor,
wherein the switch performs a switching operation corresponding to the first and second power source voltages.

4. The low noise amplifier of claim 3, wherein
the switch is configured turn off in response to application of the first power source voltage, and
the switch is configured to turn on in response to application of the second power source voltage.

5. The low noise amplifier of claim 1, further comprising a switch that is connected between the first terminal and a second terminal of the second transistor,
wherein the switch is configured to perform a switching operation corresponding to the first and second power source voltages.

6. The low noise amplifier of claim 5, wherein
the switch is configured turn off in response to application of the first power source voltage, and
the switch is to turn on in response to application of the second power source voltage.

7. The low noise amplifier of claim 1, wherein the first terminal of the second transistor is connected to a first terminal of the first transistor,
the first terminal of the third transistor is connected to a second terminal of the second transistor, and
the first power source voltage or the second power source voltage is applied to a second terminal of the third transistor.

8. The low noise amplifier of claim 7, further comprising:
a first inductor that is connected between a second terminal of the first transistor and a ground; and
a second inductor that is connected between a terminal to which the first power source voltage or the second power source voltage is input and the second terminal of the third transistor.

9. The low noise amplifier of claim 1, wherein the control terminal of the first transistor, a control terminal of the second transistor, and a control terminal of the third transistor are respectively applied with a bias voltage.

10. A method, comprising:
amplifying a received Radio Frequency (RF) signal by operating N transistors (here, N is a natural number of 3 or more) that are connected in a cascode structure with each other when a power source voltage is a first power source voltage; and
amplifying the RF signal by operating M transistors among the N transistors when the power source voltage is a second power source voltage,
wherein M is a natural number of less than the N.

11. The method of claim 10, wherein the first power source voltage is higher than the second power source voltage.

12. The method of claim 10, wherein the amplifying of the RF signal by operating the M transistors comprises providing a bypassing path at opposite ends of at least one transistor among the N transistors.

13. The method of claim 12, wherein the providing of the bypassing path comprises providing the bypassing path through a switch that is connected to the opposite ends of the at least one transistor.

14. The method of claim 13, wherein
when the first power source voltage is applied, the switch is turned off, and
when the second power source voltage is applied, the switch is turned on.

15. The method of claim 10, wherein
the N transistors comprise a first transistor receiving the RF signal, a second transistor connected with the first transistor with a cascode structure, and a third transistor connected with the second transistor with a cascode structure, and
the M transistors comprise the first and second transistors or the first and third transistors.

16. A low noise amplifier comprising:
a first transistor configured to receive a radio frequency (RF) signal through a control terminal;
a second transistor configured to receive an output signal of the first transistor through a first terminal of the second transistor; and
a third transistor configured to receive an output signal of the second transistor through a first terminal of the third transistor,
wherein the first to third transistors are configured to perform an amplification operation in response to application of a first power source voltage, and the first and second transistors or the first and third transistors are configured to perform an amplification operation in response to application of a second power source voltage.

17. The low noise amplifier of claim 16, wherein the second transistor forms a cascode structure with the first transistor.

18. The low noise amplifier of claim 16, wherein the third transistor forms a cascode structure with the second transistor.
